(19) United States
(12) Patent Application Publication
(10) Pub. No.: US 2017/0364624 A1
(43) Pub. Date: Dec. 21, 2017

(54) METHOD OF CALCULATING PROCESSED DEPTH AND STORAGE MEDIUM STORING PROCESSED-DEPTH CALCULATING PROGRAM

(71) Applicant: Toshiba Memory Corporation, Minato-ku (JP)

(72) Inventor: Sadatoshi MURAKAMI, Yokohama (JP)

(73) Assignee: Toshiba Memory Corporation, Minato-ku (JP)

(21) Appl. No.: 15/465,906

(22) Filed: Mar. 22, 2017

Related U.S. Application Data
(60) Provisional application No. 62/350,875, filed on Jun. 16, 2016.

(51) Int. Cl. G06F 17/50; G06F 7/523; G06F 7/50; H01L 21/67; G06F 7/548

(52) U.S. Cl. CPC G06F 17/5072; H01L 21/67242; G06F 7/548; G06F 7/50; G06F 7/523; G06F 2217/12

(57) ABSTRACT

A method of calculating a form according to an embodiment relates to a method of calculating a processed depth of a material to be etched when the material to be etched is etched using a mask material. The method comprises calculating a first opening solid angle Ω1 based on an opening of a mask pattern, the first opening solid angle Ω1 defining an incident quantity of ions contributing to etching, and calculating a second opening solid angle Ω2 based on an opening of a mask pattern, the second opening solid angle Ω2 defining an incident quantity of depositions. A processed depth at a process point where the material to be etched is etched is calculated based on a linear equation using the first opening solid angle Ω1 and the second opening solid angle Ω2 as variables.

### CROSS REFERENCE TO RELATED APPLICATION

This application is based upon and claims the benefit of priority from U.S. Provisional Patent Application No. 62/350,875, filed on Jun. 16, 2016, the entire contents of which are incorporated herein by reference.

### FIELD

An embodiment described herein generally relates to a method of calculating a processed depth and a storage medium storing a processed-depth calculating program.

### BACKGROUND

As microfabrication of semiconductor devices progresses, it is required to acquire a difference between a mask pattern and a pattern transferred on a wafer more correctly. Under these requirements, a method of calculating a processed form of a material to be etched by calculating a difference between a mask pattern and a pattern on a wafer as a dimension conversion difference (an etching bias) is proposed.

However, in a known method being proposed, it may calculate only a processed form of a material to be etched in a lateral direction. In semiconductor devices, with regard to contact holes or trench structures, it is required to process holes or trenches with a high aspect ratio in which a size in a longitudinal direction thereof is larger than a size in a lateral direction thereof. For this reason, it is required to calculate a processed depth of a material to be etched in a vertical direction, that is to say, a longitudinal direction in manufacturing semiconductor devices.

However, in a known method of calculating processed form, a calculated processed form only has information on a planar direction (a lateral direction), and does not have information on a depth direction (a longitudinal direction) which causes problems in high-aspect-ratio process. Then, it is impossible to obtain any knowledge about bottom forms of holes or trenches in processed patterns, whereas information on processed forms of upper portions (in the proximity of a surface) of processed patterns or average processed forms may be obtained. Thus, it is difficult to optimize pattern layouts at a design stage. In order to avoid it, it is possible to actually repeat trial manufacture, but there may be a possibility of causing lengthening of a development period and increase in cost.

### BRIEF DESCRIPTION OF THE DRAWINGS

FIG. 1 is a conceptual diagram for explaining a first embodiment showing an example of a high-aspect-ratio trench process.

FIG. 2 is a conceptual diagram for explaining a method of calculating a processed-depth according to a first embodiment.

FIG. 3 is a conceptual diagram for explaining a method of calculating a processed-depth according to a first embodiment.

FIG. 4 is a graph showing a relationship between an azimuth angle θ1 and θ2, and incident quantities of ions or depositions.

FIG. 5 is a graph showing a relationship between an opening width W of mask and a processed depth D.

FIG. 6 is a contour drawing and a graph of processed-depth D calculated at a plurality of process point Pd, respectively.

FIG. 7 is a flow chart showing steps in a method of calculating a processed depth according to a first embodiment.

FIG. 8 is a block diagram showing a configuration of the computer 10 for executing a method of calculating a processed depth according to a first embodiment.

FIG. 9 is a conceptual diagram for explaining a method of calculating a processed depth according to a second embodiment.

FIG. 10 is a graph for explaining a method of calculating a processed depth according to a second embodiment.

FIG. 11 is a graph for explaining a third embodiment.

### DETAILED DESCRIPTION

A method of calculating form according to an embodiment described herein generally relates to a method of calculating processed depth for calculating a processed-depth of a material to be etched when the material to be etched is etched using mask material. In this method, the first opening solid angle Ω1 which defines an incident quantity of ions contributing to etching is calculated based on an opening of a mask pattern. The second opening solid angle Ω2 which defines an incident quantity of depositions is calculated based on an opening of a mask pattern. A processed depth at a process point is calculated based on a linear equation using the first opening solid angle Ω1 and the second opening solid angle Ω2 as variables.

Next, a method of calculating a process-depth and a processed-depth calculating program according to embodiments will be described in detail with reference to the drawings.

### First Embodiment

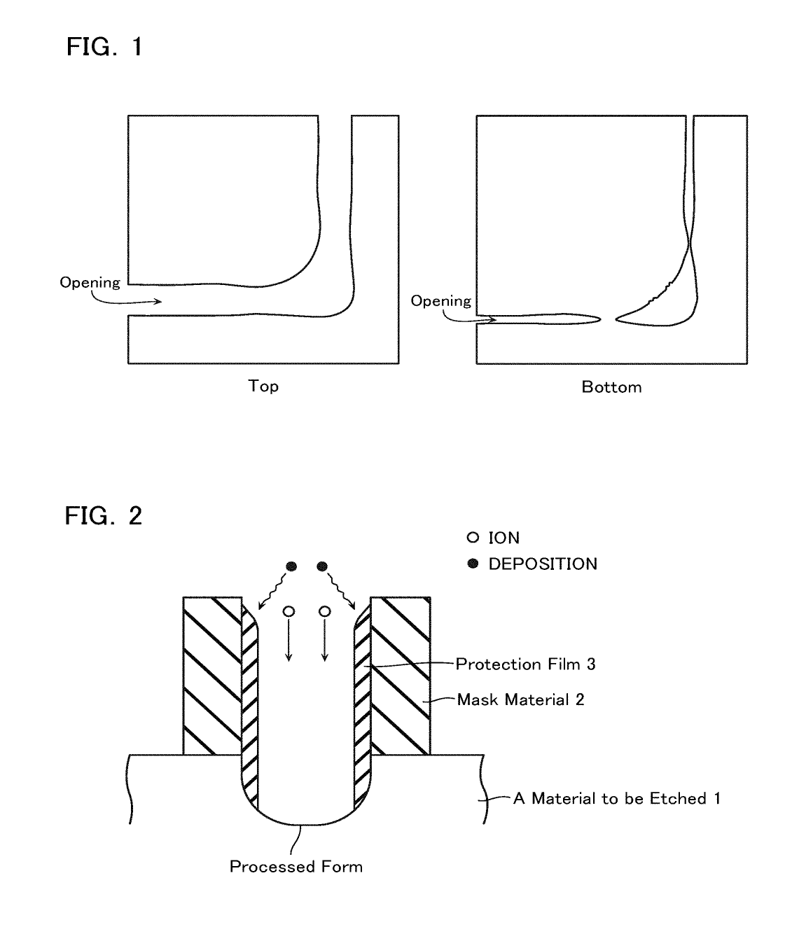

A method of calculating a processed depth and a processed-depth calculating program according to a first embodiment will be described in detail with reference to FIGS. 1-8.

### (Brief Summary of a Method of Calculating a Process Depth)

A method of calculating a processed depth and a program relate to a method of calculating a processed depth and a program for calculating a processed depth of a material to be etched when a processing method in which the material to be etched is etched using a mask material is used.

FIG. 1 is a conceptual diagram for explaining a first embodiment, showing an example of processing of a high-aspect-ratio trench. As shown in a picture of FIG. 1, in the proximity of the upper surface of the material to be etched, a high-aspect-ratio trench is etched in a form almost approximate to an etching pattern formed by a mask material for etching. On the other hand, at the bottom of a trench, due to various causes, a desired trench form is not obtained and closures (unetched portions) occur at a part of a trench. The present embodiment is aimed at calculating a processed depth in a high-aspect-ratio processing to prevent such closures.

FIG. 2 is a conceptual diagram for explaining a method of calculating a processed depth according to the first embodiment. In etching technology for forming deep trenches, ions are generated from supplied gas by plasma discharge. Generated ions are accelerated by a high electrical field generated between plasma and a wafer substrate, and collide with a surface of the material to be etched 1, thereby removing part of the material to be etched 1. On the other hand, by depositing depositions due to the supply gas, the deposition film 3 is formed on a side surface of the mask material 2 and on a side surface of the material to be etched 1. The deposition film 3 is formed as a protection mask for protecting side surfaces of the mask material 2 and the material to be etched 1.

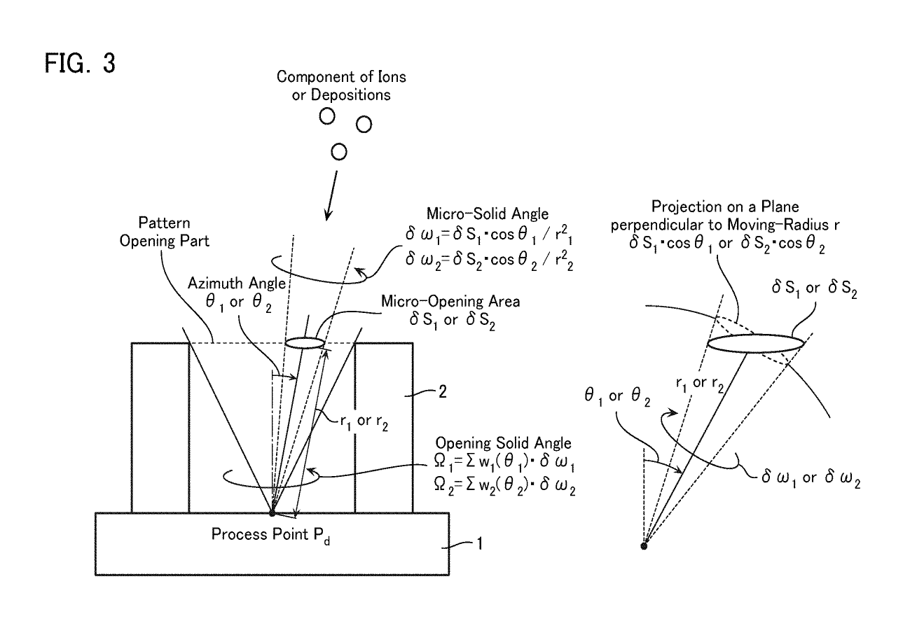

In the method of calculating a processed depth according to the present embodiment, a factor based onions which progress etching and a factor based on depositions which progress depositing are calculated, respectively. A processed depth D at a certain process point Pd of the material to be etched 1 is calculated based on the above two factors. The factor based on ions is the opening solid angle Ω1, and quantity of ions to be supplied to the process point Pd is proportional to the opening solid angle Ω1, as shown in FIG. 3. The opening solid angle Ω1 is determined by a mask pattern of the mask material 2.

On the other hand, the factor based on the depositions is the opening solid angle Ω2, and quantity of depositions is proportional to the opening solid angle Ω2. The opening solid angle Ω2 is also determined by a mask pattern of the mask material 2.

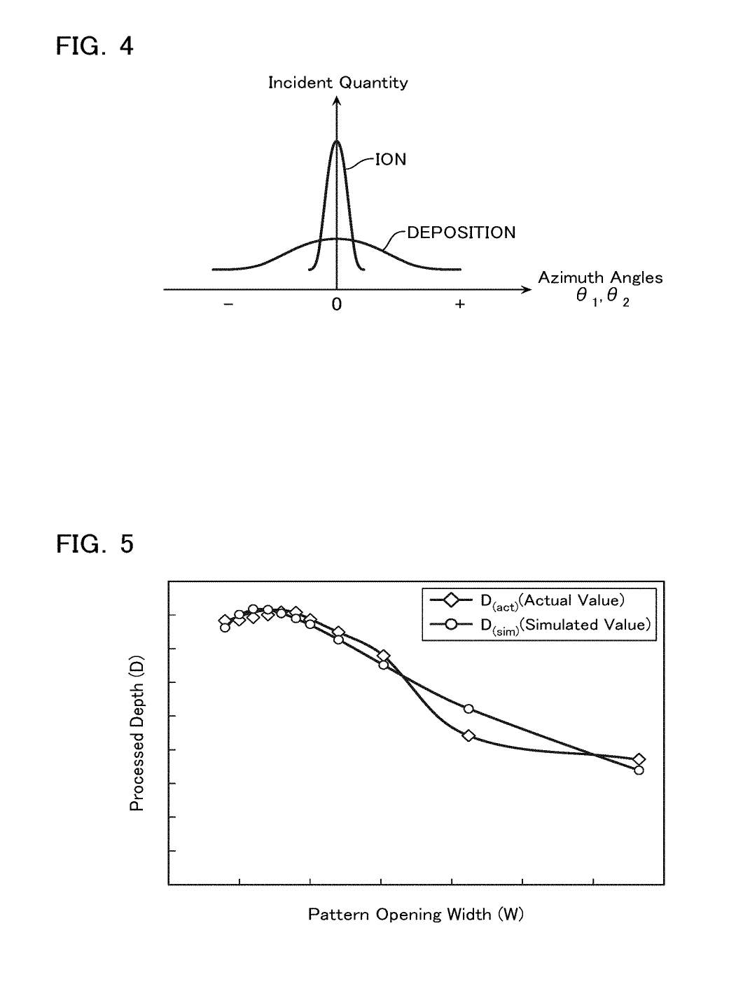

Ions are moved by an accelerating voltage of an etching apparatus. As shown in FIG. 4, incident quantity has a large peak at the azimuth angle θ1=0 (in a direction perpendicular to the surface of the material to be etched 1). As the absolute value of the azimuth angle θ1 becomes larger, incident quantity of ions rapidly becomes smaller. On the other hand, as depositions move in random directions, as shown in FIG. 4, the change of incident quantity is gradual over the broad azimuth angle θ2. For this reason, regarding the opening solid angles Ω1 and Ω2, it is necessary to perform calculation with modulation so as to show angle dependence as shown in FIG. 4.

According to these two opening solid angle Ω1 and Ω2, the processed depth D at the process point Pd is represented by following formula (1).

D=a*Ω1+b*Ω2+c [formula (1)]

Where a, b, and c are constants.

The constants a, b, and c are determined so that a graph showing a relationship between an opening width W of a mask pattern and a simulated processed depth D(sim) becomes most similar to a graph showing a relationship between an opening width W of a mask pattern and an actually measured processed depth D(act) as shown in FIG. 5.

The coefficient a that is multiplied by the opening solid angle Ω1 related to ions has a positive value, whereas the coefficient b that is multiplied by the opening solid angle Ω2 related to depositions has a negative value (b<0). This is because the former contributes to progress of etching, whereas the latter contributes to depositing, which leads to prevent etching from progressing.

Thus, the processed depth D at the process point Pd is represented by a linear equation using quantity of ions proportional to the opening solid angle θ1 and quantity of depositions proportional to the opening solid angle θ2. Thus, it becomes possible to predict a distribution of the processed depth D correctly by independently calculating the opening solid angles θ1 and θ2 for ions and depositions in etching, respectively, and using them for calculating the processed depth D.

Note that the opening solid angles Ω1 and Ω2 are defined as values by integrating micro-solid angles δω over the whole area of an opening of a mask pattern with weighting coefficients, and may be calculated by [formula (2)] below.

$$\begin{matrix}Ω1 = Σ {w}_{1} ( {θ}_{1} ) * {δω}_{1} \\ = Σ {w}_{1} ( {θ}_{1} ) * δ {S}_{1} * cos {θ}_{1} / {r}_{1}^{2}\end{matrix} \\ \begin{matrix}Ω2 = Σ {w}_{2} ( {θ}_{2} ) * {δω}_{2} \\ = Σ {w}_{2} ( {θ}_{2} ) * δ {S}_{2} * cos {θ}_{2} / {r}_{2}^{2}\end{matrix} \qquad [ Formula ( 2 ) ]$$

Here, w₁ (θ₁) and w₂ (θ₂) are weighting coefficients which use angles θ₁ and θ₂ as their functions. δS₁ and δS₂ are micro-opening areas, r₁ and r₂ are distances between the process point Pd and the centers of the micro-opening areas δS₁ and δS₂. That is, the opening solid angles Ω1 and Ω2 are calculated as a value obtained by multiplying the micro-opening areas δS₁ and δS₂ by cos θ₁ and cos θ₂, dividing results of the multiplying by squares of distances r₁ and r₂ between the evaluation point and the center of the micro-opening areas δS₁ and δS₂, and integrating results of the dividing over the opening part of the mask pattern. The weighting coefficients w₁ (θ₁) and w₂ (θ₂) have the maximum when the azimuth angles are θ₁=0, θ₂=0, and have smaller values as θ₁ and θ₂ become greater. The weight w₁ (θ₎ may be represented by a formula of w₁ (θ₁)=cosⁿ(θ₁), the similar applies to weight w₂(θ₂). Also, the weight w₁(θ₁) may be represented by a formula of exp[−(r₁*sin(θ₁))²/σ²]. The same applies to weight w₂(θ₂).

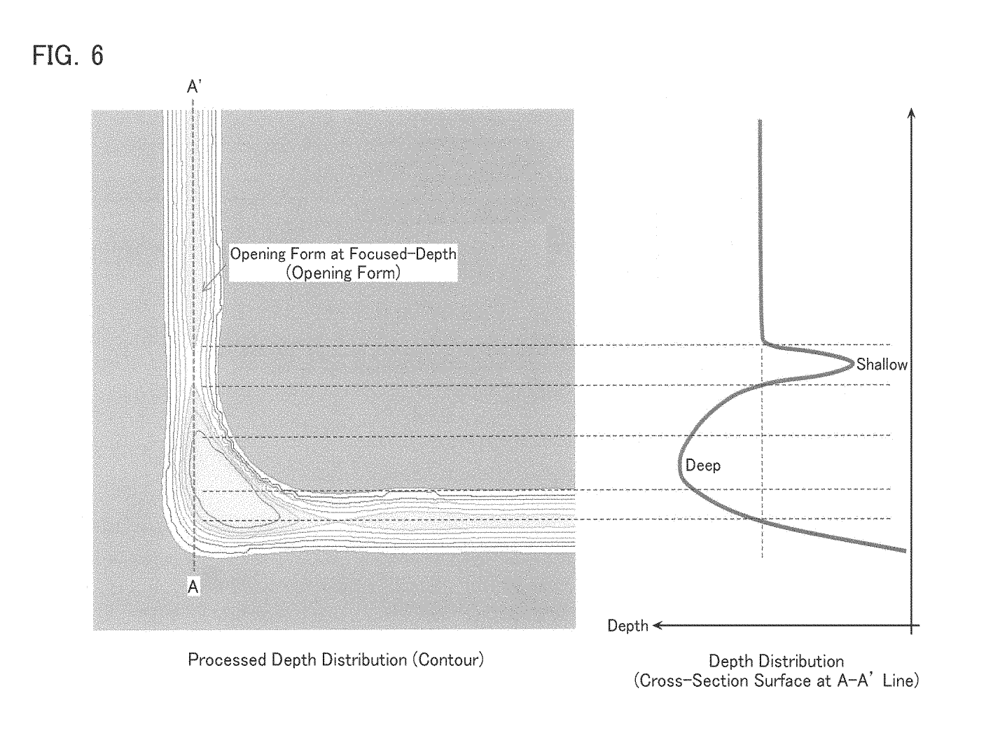

As described above, by calculating the processed depths D at a plurality of process points Pd respectively, as shown in the left side of FIG. 6, it becomes possible to draw a state (a contour drawing) of the processed depths D. The graph on the right side of FIG. 6 shows the distribution of the processed depths D along A-A′ line in the contour drawing on the left side of FIG. 6. A three-dimensional profile drawing can be drawn instead of the contour drawing of FIG. 6. According to these output results, portions where etching residue occurs are represented.

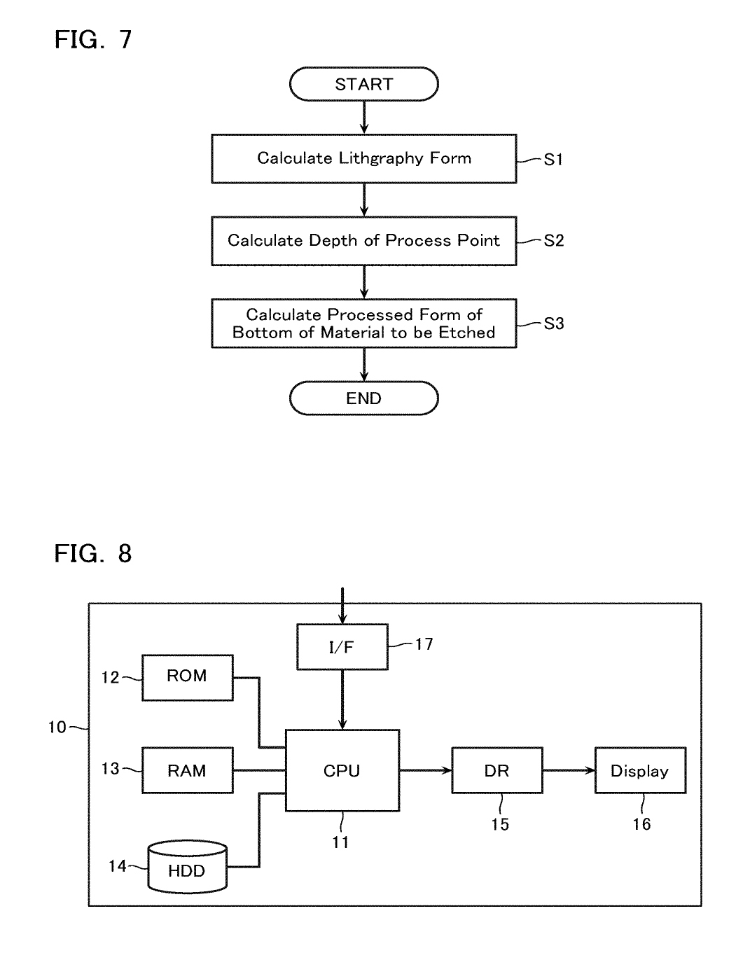

FIG. 7 is a flow chart showing steps in a method of calculating a processed depth according to the first embodiment. A lithography form of the mask material 2 formed in lithography process is firstly calculated (S1). Calculation of the processed depth can be performed according to the calculation results (S2, S3).

FIG. 8 is a block diagram showing a configuration of the computer 10 for executing the above described method of calculating a processed depth. The computer 10 comprises a CPU 11, an ROM 12, an RAM 13, a hard disk drive 14, a display regulator 15, a display 16, and an input/output interface 17. The hard disk drive 14 functions as a storage medium storing a processed-depth calculating program for executing the above describe method of calculating processed depth. The processed-depth calculating program is read from the hard disk drive 14, transferred to the RAM 13, and stored therein. The CPU 11 executes the above described method of calculating processed depth according to the processed-depth calculating a program and various data input from the input/output interface 17.

[Advantage]

According to the first embodiment, it becomes possible to predict a processed form of the material to be etched 1 not only in a direction along a surface of the material to be etched 1 (a lateral direction), but also in a direction perpendicular to the surface of the material to be etched 1 (a depth direction).

### Second Embodiment

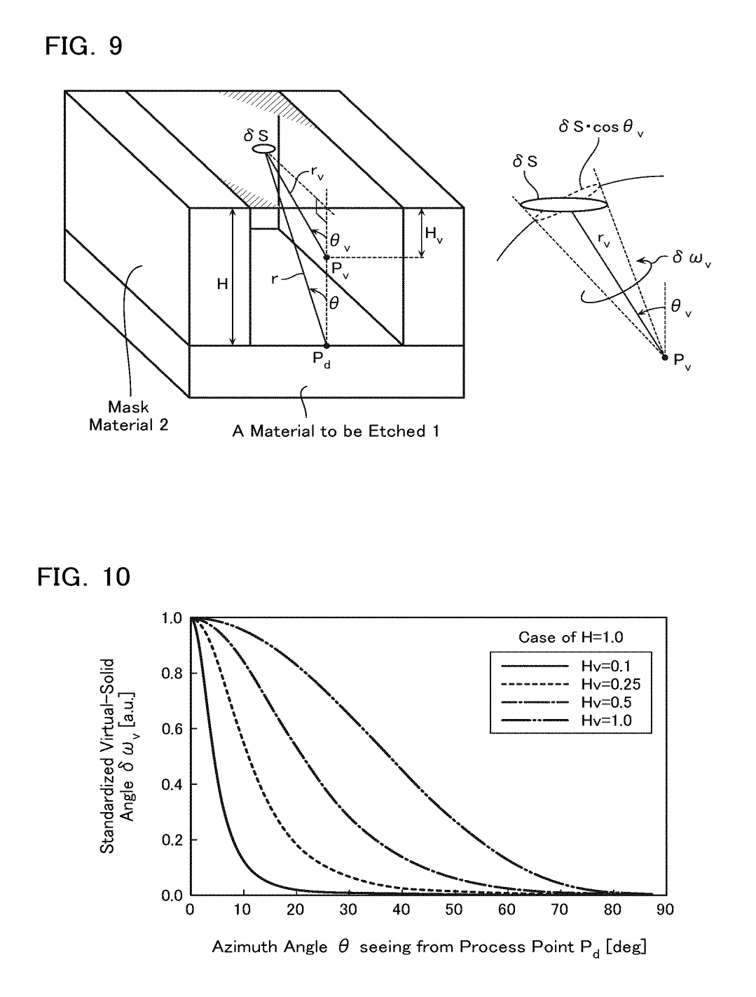

Next, a method of calculating processed depth and a program according to a second embodiment will be described with reference to FIG. 9. A method of calculating processed depth according to this embodiment is, similar to the first embodiment, used for predicting a processed form of the material to be etched 1 not only in a direction along a surface of the material to be etched 1 (a lateral direction), but also in a direction perpendicular to the surface of the material to be etched 1 (a depth direction).

### Second Embodiment

However, in this embodiment, a method of calculating the opening solid angles Ω1 and Ω2 is different from the first embodiment. In the first embodiment, the weighting coefficients w₁(θ₁) and w₂(θ₂) are multiplied when the opening solid angles Ω1 and Ω2 are calculated. On the other hand, in the second embodiment, a height of an evaluation point which is used for calculating the opening solid angles Ω1 and Ω2 using ions and depositions, is virtually changed. A virtual evaluation point is, as explained in detail below, provided directly above the process point Pd along the normal line to a surface of the pattern opening of the mask material, seeing from the process point Pd.

A method of calculating the opening solid angles Ω1 and Ω2 using a virtual evaluation point will be described hereinafter with reference to FIG. 9.

The process point Pd on a surface of the material to be etched 1 is discussed here. The mask material 2 having a height of H is deposited on the material to be etched 1, and a surface of a pattern opening is formed on an uppermost part of the mask material 2. Here, considering a micro-opening having an area δS on the surface of the pattern opening, and an azimuth angle of the micro-opening δS seeing from the process point Pd is defined as θ. In addition, a virtual evaluation point Pᵥ is provided in vertically upper direction from the process point Pd. The azimuth angle of the micro-opening δS seeing from the virtual evaluation point Pd is defined as θᵥ. A height from the virtual evaluation point Pᵥ to the pattern opening part is defined as Hᵥ (<H). A distance from the virtual evaluation point Pᵥ to the micro-opening 5S is defined as rᵥ (refer to left side of FIG. 9).

Then, a virtual solid angle δωᵥ of the micro-opening δS seeing from the virtual evaluation point Pᵥ can be represented by the following formula (3) (refer to the right side of FIG. 9).

$${δω}_{v} = δ S \cdot \frac{cos {θ}_{v}}{{r}_{v}^{2}} = δ S \cdot \frac{{H}_{v} / {r}_{v}}{{r}_{v}^{2}} = δ S \cdot \frac{{H}_{v}}{{r}_{v}^{3}} \qquad [ Formula ( 3 ) ]$$

In formula (3), δS is a constant value. Therefore, it is understood that a value of the virtual solid angle δωᵥ is a function of Hᵥ and rᵥ. FIG. 10 shows a graph in which values of the virtual solid angle δωᵥ are plotted with the azimuth angles θ assigned thereto. The graph of FIG. 10 shows a relationship between the azimuth angles θ and the virtual solid angles δωᵥ in a case where a height H of the mask material 2 is set to be 1 and a virtual height Hᵥ is changed to 0.1, 0.25, 0.5, and 1.

Also, since a value of the virtual solid angle δωᵥ greatly varies according to the virtual height Hᵥ, the standardized virtual solid angle δωᵥ is shown in vertical axis so that a value of the virtual solid angle δωᵥ is set to be 1 when the azimuth angle θ=0 [deg].

According to the graph in FIG. 10, it is possible to change dependence property of the virtual solid angle δωᵥ on the azimuth angle θ by changing a value of the virtual height Hᵥ. That is, it may reproduce azimuth angle dependencies of incident quantity that differs between ions and depositions as shown in FIG. 4, by a calculation of the virtual solid angle δωᵥ while adjusting the virtual height Hᵥ.

[Advantage]

According to the second embodiment, similar to the first embodiment, it becomes possible to predict a processed form of the material to be etched 1 not only in a direction along the surface of the material to be etched 1 (a lateral direction), but also in a direction perpendicular to the surface of the material to be etched 1 (a depth direction).

### Third Embodiment

Next, a method of calculating processed depth and a program according to a third embodiment will be described. The method according to the third embodiment is more preferable for predicting a processed depth of larger opening-dimension area compared to the aforementioned embodiments.

A method of calculating a processed depth according to the third embodiment is, similar to the first embodiment, meant for predicting a processed form of the material to be etched 1 not only in a direction along the surface of the material to be etched 1 (a lateral direction), but also in a direction perpendicular to the surface of the material to be etched 1 (a depth direction). Here, in the present embodiment, a third opening solid angles Ω3 is calculated in addition to the opening solid angles Ω1 and Ω2. The third opening solid angle Ω3 functions as a correction term in a case in which a processed depth D is calculated at a larger opening-dimension area.

In the third embodiment, a processed depth D at the process point Pd is calculated according to the following formula (4).

D=a*Ω1+b*Ω2+d*Ω3+c [Formula (4)]

Note that a, b, c and d are constants (b is a negative value). The constants a, b, c and d can be determined by a method similar to that of the first embodiment.

The opening solid angles Ω1, Ω2 and Ω3 can be calculated in a similar way to the aforementioned embodiments.

[Advantage]

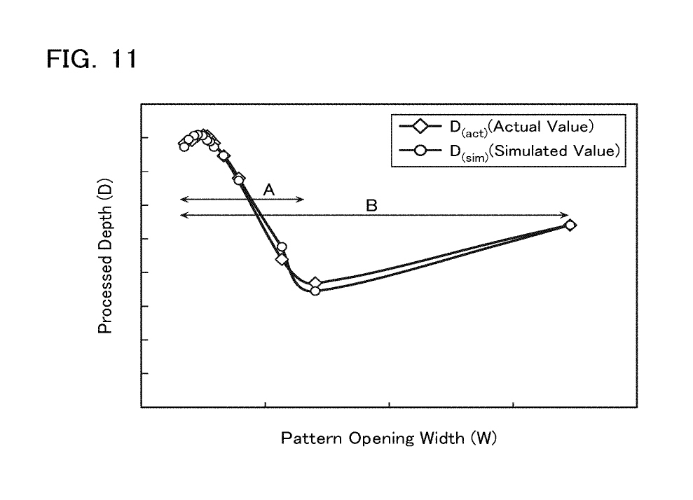

According to the third embodiment, similar to the aforementioned embodiment, it becomes possible to predict a processed form of the material to be etched 1 not only in a direction along the surface of the material to be etched 1 (a lateral direction), but also in a direction perpendicular to the surface of the material to be etched 1 (a depth direction). In addition, according to the present embodiment, it becomes possible to calculate a processed depth for an opening-dimension area of a wider range. Specifically, as shown in FIG. 11, whereas a processed depth is calculated for the narrow opening-dimension area shown by arrow A in the first embodiment, it becomes possible to calculate a processed depth for the opening-dimension area of much wider range shown by arrow B in the present embodiment.

[Modification]

Embodiments described above are only examples and can be modified in a various way within a scope of the present inventions. For example, although in the above described embodiments, a single opening solid angle Ω1 with respect to ions and a single opening solid angle Ω2 with respect to depositions are calculated, regarding ions, separate opening solid angles can be calculated for each kind of ions. For instance, when there are a first component, a second component, . . . , and an n-th component as ions contributing to etching, it is possible to calculate opening solid angles Ω1₁, Ω1₂, . . . , and Ω1ₙ of the first, second, . . . , and n-th components, respectively. Also, when there are a first deposition, a second deposition, . . . , and an n-th deposition as depositions contributing to depositing, it is possible to calculate opening solid angles Ω2₁, Ω2₂, . . . , and Ω2ₙ of the first, second, . . . , and n-th depositions, respectively. Then, a process depth D can be calculated by following formula (5).

D=a1*Ω1₁+a2*Ω1₂+ . . . +an*Ω1ₙ+b1*Ω2₁+b2*Ω2₂+ . . . +bm*Q2ₘ+c [Formula (5)]

Where a1-an, b1-bm, and c are constants, and b1-bm have negative values.

[Other]

While certain embodiments have been described, these embodiments have been presented by way of example only, and are not intended to limit the scope of the inventions. Indeed, the novel methods and systems described herein may be embodied in a variety of other forms: furthermore, various omissions, substitutions and changes in the form of the methods and systems described herein may be made without departing from the spirit of the inventions. The accompanying claims and their equivalents are intended to cover such forms or modifications as may fall within the scope and spirit of the inventions.

What is claimed is:

1. A method of calculating a processed depth for calculating a processed depth of a material to be etched when the material to be etched is etched using a mask material,
the method comprises:
calculating a first opening solid angle Ω1 based on an opening of a mask pattern, the first opening solid angle Ω1 defining an incident quantity of ions contributing to etching;
calculating a second opening solid angle Ω2 based on an opening of a mask pattern, the second opening solid angle Ω2 defining an incident quantity of depositions; and
calculating a processed depth at a process point where the material to be etched is etched based on a linear equation using the first opening solid angle Ω1 and the second opening solid angle Ω2 as variables.

2. The method of calculating a processed depth according to claim 1, wherein
the first opening solid angle Ω1 and the second opening solid angle Ω2 are calculated as values obtained by multiplying an area of a micro-opening by a cosine of an azimuth angle, dividing a result of the multiplying by a square of a distance from an evaluation point to the micro-opening, and integrating results of the dividing over the opening of the mask pattern.

3. The method of calculating a processed depth according to claim 1, wherein
the processed depth is calculated by:
multiplying coefficients to the first opening solid angle Ω1 and the second opening solid angle Ω2, respectively; and
summing multiplied values obtained by the multiplying.

4. The method of calculating a processed depth according to claim 2, wherein
the first opening solid angle Ω1 and the second opening solid angle Ω2 are calculated by weighting based on an angle from the process point to the micro-opening area.

5. The method of calculating a processed depth according to claim 4, wherein
the weighting is expressed by a formula of cosⁿ(θ) (where θ expresses an azimuth angle).

6. The method of calculating a processed depth according to claim 4, wherein
the weighting is expressed by a formula of exp[−{r*sin(θ)}²/σ²] when an azimuth angle is e (where r expresses a distance between the micro-opening area and the evaluating point).

7. The method of calculating a processed depth according to claim 1, wherein
the processed depth is calculated by:
multiplying coefficients to the first opening solid angle Ω1 and the second opening solid angle Ω2, respectively;
summing multiplied values obtained by the multiplying; and
adding a value obtained by multiplying a coefficient to a third opening solid angle Ω3 to summed value obtained by the summing.

8. A Storage medium storing a processed-depth calculating program for calculating a processed depth of a material to be etched when the material to be etched is etched using a mask material, wherein
the program makes a computer execute:
calculating a first opening solid angle Ω1 based on an opening of a mask pattern, the first opening solid angle Ω1 defining an incident quantity of ions contributing to etching;
calculating a second opening solid angle Ω2 based on an opening of a mask pattern, the second opening solid angle Ω2 defining an incident quantity of depositions; and
calculating a processed depth at a process point where the material to be etched is etched based on a linear equation using the first opening solid angle Ω1 and the second opening solid angle Ω2 as variables.

9. The storage medium according to claim 8, wherein
the first opening solid angle Ω1 and the second opening solid angle Ω2 are calculated as values obtained by integrating micro-opening area over the opening of the mask pattern.

10. The storage medium according to claim 8, wherein
the processed depth is calculated by:
multiplying coefficients to the first opening solid angle Ω1 and the second opening solid angle Ω2, respectively; and
summing multiplied values obtained by the multiplying.

11. The storage medium according to claim 8, wherein
the first opening solid angle Ω1 and the second opening solid angle Ω2 are calculated by weighting based on an angle from the process point to the micro-opening area.

12. The storage medium according to claim 11, wherein
the weighting is expressed by a formula of cosⁿ(θ) (where θ expresses an azimuth angle).

13. The storage medium according to claim 11, wherein
the weighting is expressed by a formula of exp[−(r*sin(θ))²/σ²] when an azimuth angle is θ.

14. The storage medium according to claim 11, wherein
the processed depth is calculated by:
multiplying coefficients to the first opening solid angle Ω1 and the second opening solid angle Ω2, respectively;
summing multiplied values obtained by the multiplying; and
adding a value obtained by multiplying a coefficient to a third opening solid angle Ω3 to summed value obtained by the summing.
